(19) United States
(12) Patent Application Publication
(10) Pub. No.: US 2025/0212413 A1
(43) Pub. Date: Jun. 26, 2025

(54) ELECTRONIC DEVICES, RELATED SYSTEMS, AND METHODS OF FORMING

(71) Applicant: Micron Technology, Inc., Boise, ID (US)

(72) Inventors: Yun Huang, Singapore (SG); Yifen Liu, Meridan, ID (US); Xin Lan, Singapore (SG); Byeung Chul Kim, Boise, ID (US); Ye Xiang Hong, Singapore (SG); Sok Han Wong, Singapore (SG); Gianpietro Carnevale, Bottanuco (IT)

(21) Appl. No.: 18/956,820

(22) Filed: Nov. 22, 2024

Related U.S. Application Data
(60) Provisional application No. 63/613,527, filed on Dec. 21, 2023.

(51) Int. Cl. H10B 43/35; H01L 21/3105; H01L 21/768; H01L 23/528; H01L 23/532

(52) U.S. Cl. CPC H10B 43/35; H01L 21/31053; H01L 21/7682; H01L 23/5283; H01L 23/5329

(57) ABSTRACT

An electronic device includes a stack structure including vertically alternating dielectric materials and conductive materials. The dielectric materials define air gaps between vertically adjacent conductive materials and include a first oxide material vertically adjacent to the conductive materials and laterally adjacent to the tunneling material, and a nitride material laterally and vertically adjacent to the first oxide material. The stack structure includes pillars extending vertically through the stack structure, the pillars including cell films adjacent to the dielectric and conductive materials. The cell films include a high-k dielectric material, a barrier oxide material, a storage node material, a tunneling material, and a channel material, wherein segments of each of the high-k dielectric material, the barrier oxide material, and the storage node material are adjacent to the conductive materials. Related methods and systems are also disclosed.

### CROSS-REFERENCE TO RELATED APPLICATION

This application claims the benefit under 35 U.S.C. § 119 (e) of U.S. Provisional Patent Application Ser. No. 63/613,527, filed Dec. 21, 2023, the disclosure of which is hereby incorporated herein in its entirety by this reference.

### TECHNICAL FIELD

The disclosure, in various embodiments, relates generally to the field of electronic devices and electronic device fabrication. More particularly, the disclosure relates to electronic devices comprising dielectric materials including an oxide material and a nitride material intervening between conductive materials of the electronic device, and to related methods and systems.

### BACKGROUND

A continuing goal of the electronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures.

Conventional 3D NAND Flash memory devices include a vertical memory array with vertical memory strings including memory cells extending through openings in one or more stack structures including conductive materials and dielectric materials. The memory cells operate by movement of charge between a channel material and a storage node material (i.e., a storage nitride material, a charge storage material). Programming of a memory cell may include moving the charge (e.g., electrons) from the channel material into the storage node material and storing the charge within the storage node material. Erasing a memory cell may include moving holes into the storage node material to recombine with the electrons stored in the storage node material, releasing charge from the storage node material. Conventional memory cells often include a continuous storage node material which extends across multiple memory cells of the memory array. The continuous storage node material may lead to charge migration from one memory cell to another, resulting in cell to cell interference and data retention problems. However, a discontinuous storage material may result in an active cell area of the memory cells which is too narrow to achieve desired program/erase windows. Conventional memory cells also exhibit poor word line to word line leakage and a low breakdown voltage.

### BRIEF DESCRIPTION OF THE DRAWINGS

FIGS. 1A through 1D are cross-sectional views at various stages of forming an electronic device according to embodiments of the disclosure;

FIG. 1E is a top-down cross-sectional view of the electronic device of FIG. 1D taken along the A-A line in FIG. 1D;

FIG. 2 is a cross-sectional view of an enlarged portion of the electronic device of FIG. 1E;

FIG. 3 is a cross-sectional view of an enlarged portion of an electronic device according to additional embodiments of the disclosure;

FIG. 4 is a cross-sectional view of an enlarged portion of an electronic device according to other embodiments of the disclosure;

FIG. 5 is a partial cutaway perspective view of an electronic device according to embodiments of the disclosure; and

FIG. 6 is a block-diagram of an electronic system according to embodiments of the disclosure.

### DETAILED DESCRIPTION

Electronic devices (e.g., an apparatus, a semiconductor device, a memory device) that include vertically alternating dielectric materials and conductive materials, the dielectric materials including at least one first oxide material vertically adjacent to the conductive materials and at least one nitride material laterally and vertically adjacent to the at least one first oxide material are disclosed. The dielectric materials may define air gaps between vertically adjacent conductive materials. The stack structure may include pillars extending vertically through the stack structure, the pillars including cell films adjacent to the dielectric and conductive materials. The cell films may include a high-k dielectric material, a barrier oxide material, a storage node material, a tunneling material (e.g., an electron and hole tunneling material), and a channel material. Segments of each of the high-k dielectric material, the barrier oxide material, and the storage node material may be adjacent to the conductive materials.

The dielectric materials may include one or more of at least one second high-k dielectric material laterally and vertically adjacent to the at least one nitride material and a at least one second oxide material laterally and vertically adjacent to the at least one second high-k dielectric material or the at least one nitride material. The electronic devices including the dielectric materials including the at least one first oxide material and the at least one nitride material may advantageously exhibit an improved dielectric breakdown voltage relative to conventional electronic devices. Additionally, the at least one nitride material may act as an electron sink, preventing electron back injection into memory cells of the electronic device. By preventing electron back injection, the program/erase window of electronic devices including the dielectric materials including the at least one nitride material may be increased relative to conventional electronic devices.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed using conventional techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances are to be expected. Thus, embodiments described herein are not to be construed as being limited to the particular shapes or regions as illustrated, but include deviations in shapes that results, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0percent of the numerical value, within a range of 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of”' the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “configured” refers to a size, shape, material composition, and arrangement of one or more of at least one structure and at least one apparatus facilitating operation of one or more of the structure and the apparatus in a pre-determined way.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, the term “high-k dielectric material” means and includes a dielectric oxide material having a dielectric constant greater than the dielectric constant of silicon oxide (SiOₓ), such as silicon dioxide (SiO₂). The high-k dielectric material may include, but is not limited to, a high-k oxide material, a high-k metal oxide material, or a combination thereof. By way of example only, the high-k dielectric material may be aluminum oxide, gadolinium oxide, hafnium oxide, niobium oxide, tantalum oxide, titanium oxide, zirconium oxide, hafnium silicate, a combination thereof, or a combination of one or more of the listed high-k dielectric materials with silicon oxide.

As used herein, the term “selectively etchable” means and includes a material that exhibits a greater etch rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “sacrificial,” when used in reference to a material or a structure, means and includes a material, structure, or a portion of a material or structure that is formed during a fabrication process but which is removed (e.g., substantially removed) prior to completion of the fabrication process.

As used herein, the term “stack” or “stacks” means and includes a feature having one or more materials vertically adjacent to one another, the stacks may include alternating dielectric materials and conductive materials, such as alternating oxide materials and metal materials or alternative oxide materials and polysilicon materials. Depending on the stage of fabrication of the electronic device containing the stacks, the stacks may alternatively include alternating dielectric materials and nitride materials, such as alternating oxide materials and silicon nitride materials.

As used herein, “conductive material” means and includes an electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, a Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and conductively-doped semiconductor material (e.g., conductively-doped polysilicon, conductively-doped germanium (Ge), conductively-doped silicon germanium (SiGe)).

As used herein, “dielectric material” means and includes an electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), and a magnesium oxide (MgOₓ)), at least one dielectric nitride material (e.g., a silicon nitride (SiN_{y})), at least one dielectric oxynitride material (e.g., silicon oxynitride (SiOₓN_{y})), and at least one dielectric carboxynitride material (e.g., a silicon carboxynitride (SiOₓC_{z}N_{y})). Formulae including one or more of “x,” “” “y,” and “z” herein represent a material that contains an average ratio of “x” atoms of one element, “y” atoms of another element, and “z” atoms of an additional element (if any) for every atom of another element. Values of “x,” “y,” and “z” (if any) may be positive real integers or positive real non-integers.

As used herein, the term “substantially” in reference to a given parameter, property, or condition means and includes to a degree that one of ordinary skill in the art would understand that the given parameter, property, or condition is met with a degree of variance, such as acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, the term “substrate” means and includes a material (e.g., a base material) or construction upon which additional materials are formed. The substrate may be an electronic substrate, a semiconductor substrate, a base semiconductor layer on a supporting structure, an electrode, an electronic substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

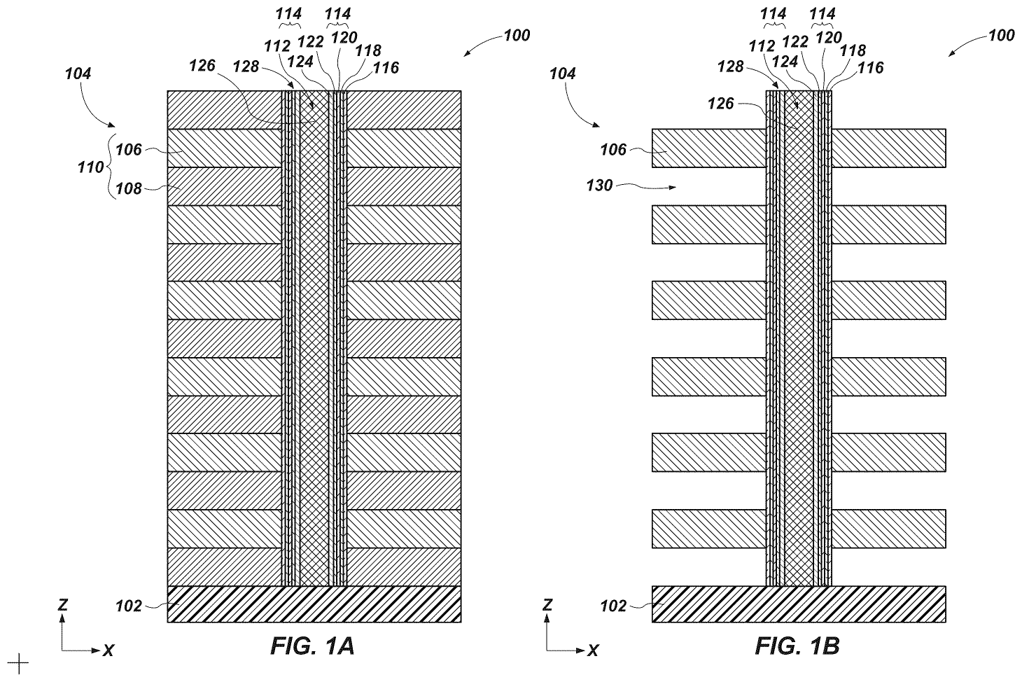

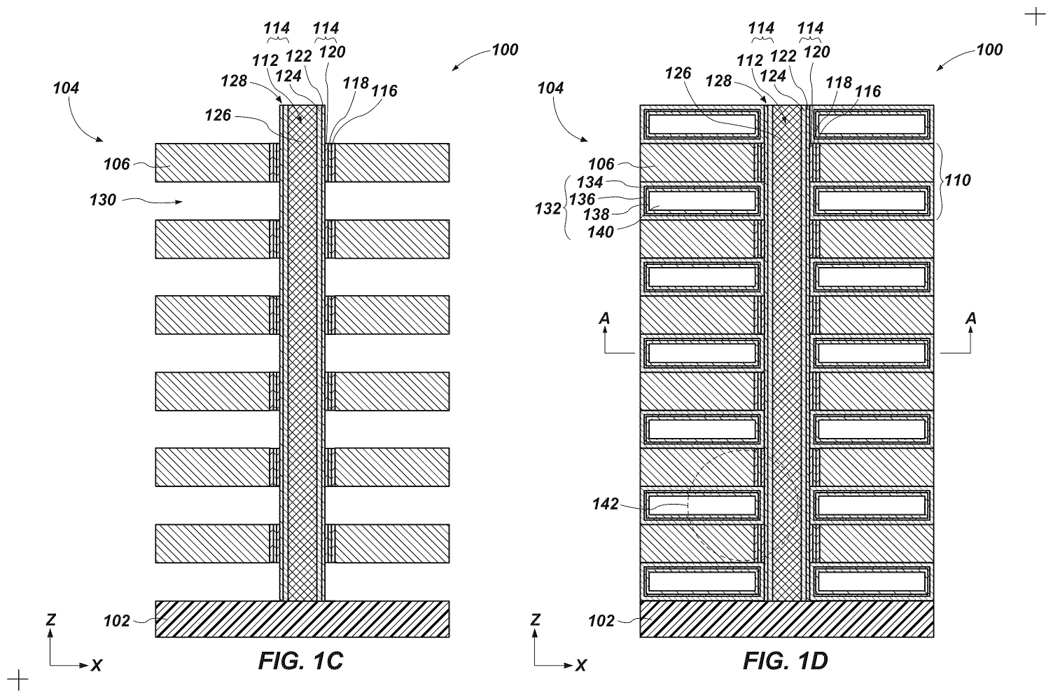

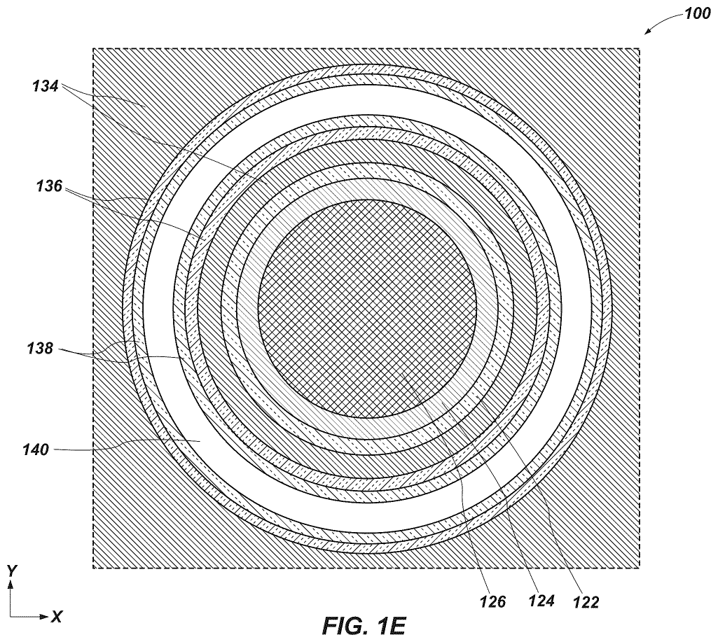

FIGS. 1A through 1E illustrate a method of forming an electronic device 100 (e.g., a memory device, a microelectronic device) including memory cells, at various stages of the method, according to embodiments of the disclosure. For simplicity, the formation of a single opening in which the memory cells are formed is illustrated, but it will be understood by one of ordinary skill in the art that the method may include simultaneously forming multiple (e.g., more than one, an array of) openings in which the memory cells are ultimately to be formed. For convenience in describing FIGS. 1A through 1E, a first direction is defined, shown in FIGS. 1A through 1E, as the X-direction. A second direction, which is transverse (e.g., perpendicular) to the first direction is defined, shown in FIGS. 1A through 1D, as the Z-direction. A third direction, which is transverse to the first and second directions is defined, as shown in FIG. 1E, as the Y-direction. Similar directions are defined, as shown in FIGS. 2 through 4, as discussed in greater detail below.

The electronic device 100 according to embodiments of the disclosure may be formed as shown in FIGS. 1A through 1D, which are cross-sectional views of the electronic device 100 during fabrication. Referring to FIG. 1A, a stack structure 104 may be formed to include one or more tiers 110 including vertically (e.g., in the Z-direction) alternating conductive materials 106 and dielectric materials 108 overlying a substrate (e.g., a base material 102). The stack structure 104 may include multiple vertically alternating conductive materials 106 and dielectric materials 108. A vertically adjacent conductive material 106 and dielectric material 108 form a tier 110. The base material 102 may, for example, be a conductive material, such as a source. The base material 102 may be formed of and include polycrystalline silicon (e.g., doped polycrystalline silicon).

The dielectric materials 108 of the stack structure 104 may be formed using conventional processes, which are not described in detail herein. As a non-limiting example, the dielectric materials 108 may be formed through one or more conventional processes (e.g., a PVD process, a CVD process, an ALD process) to form the stack structure 104.

The dielectric materials 108 may be formed of and include a sacrificial material that is selectively removable relative to the conductive materials 106. In some embodiments, the dielectric materials 108 include, consist essentially of, or consist of silicon dioxide. The dielectric materials 108 may each be at least substantially planar, and may each independently exhibit any suitable height in the Z-direction. In some embodiments, a height of the dielectric materials 108 may be within a range of from about 10 nm to about 400 nm. In some embodiments, the dielectric materials may have a height within a range of from about 10 nm to about 50 nm. Each of the dielectric materials 108 may be substantially the same (e.g., exhibit substantially the same material composition, material distribution, size, and shape) as one another, or at least one of the dielectric materials 108 may be different (e.g., exhibit one or more of a different material composition, a different material distribution, a different size, and a different shape) than at least one other dielectric material 108. The dielectric materials 108 may have the same height as the conductive materials 106 or may have a different height relative to the conductive materials 106.

A pillar opening 112 may be formed which vertically extends through the stack structure 104. As shown in FIG. 1A, the pillar opening 112 may include an elongated opening (e.g., aperture, via) exhibiting one end at an uppermost surface of the stack structure 104 and another end at a lowermost surface of the stack structure 104. The pillar opening 112 may have any suitable configuration when viewed from above, and in some embodiments may be circular, elliptical, polygonal, etc. The pillar opening 112 may be a high aspect ratio (HAR) opening extending through the tiers 110, such as having an HAR of at least about 20:1, at least about 50:1, at least about 100:1, or at least about 200:1. Sidewalls of the tiers 110 defining the pillar opening 112 may be at least substantially vertical or sloped. The pillar opening 112 may include multiple (e.g., more than one) stacked opening portions extending through the electronic device 100 if the electronic device 100 includes multiple decks (not shown). The stacked opening portions may be defined by sidewalls of the tiers 110 and upper and/or lower surfaces of the tiers 110. Sidewalls of the tiers 110 defining the stacked opening portions may be sloped.

Cell films 114 may be formed by conventional techniques adjacent to the tiers 110 along the length of the pillar opening 112 extending in the Z-direction. The cell films 114 may extend at least substantially continuously along sidewalls of the tiers 110. The cell films 114 may be conformally formed, such as by a conventional CVD process or a conventional ALD process, using conventional processing equipment. The cell films 114 may include one or more of a first high-k dielectric material 116, a barrier oxide material 118, a storage node material 120, a tunneling material 122, and a channel material 124. The first high-k dielectric material 116, the barrier oxide material 118, the storage node material 120, the tunneling material 122, and the channel material 124 may be sequentially formed.

The first high-k dielectric material 116 may be formed laterally adjacent to the tiers 110 along the length of the pillar opening 112. The first high-k dielectric material 116 may be, for example, formed from aluminum oxide, hafnium oxide, zirconium oxide, tantalum oxide, a combination thereof, or a combination of silicon oxide and one or more of the listed materials. The first high-k dielectric material 116 may be conformally formed on the sidewalls of the tiers 110. The first high-k dielectric material 116 may have an at least substantially uniform thickness extending in the X-direction. In some embodiments, the first high-k dielectric material 116 may have a thickness extending in the X-direction within a range of from about 1nm to about 5 nm.

The barrier oxide material 118 may be formed laterally adjacent to the first high-k dielectric material 116. For example, the barrier oxide material 118 may be formed by one or more of in situ growth, a CVD process, an ALD process, or a PVD process. The barrier oxide material 118 may, for example, be a charge-blocking material that is conformally formed on the first high-k dielectric material 116. The barrier oxide material 118 may be any suitable composition, such as a high quality (e.g., highly uniform and highly conformal) silicon oxide material, such as an ALD SiOₓ. The barrier oxide material 118 may have an at least substantially uniform thickness extending in the X-direction. In some embodiments, the barrier oxide material 118 may have a thickness extending in the X-direction within a range of from about 5 nm to about 10 nm.

The storage node material 120 (e.g., a nitride storage material, a charge storage material) may be formed (e.g., conformally formed) laterally adjacent to the barrier oxide material 118. For example, the storage node material 120 may be formed by conventional CVD or conventional ALD processes. As a non-limiting example, the storage node material 120 may include silicon nitride, silicon oxynitride, or a combination thereof. The storage node material 120 may have an at least substantially uniform thickness extending in the X-direction. In some embodiments, the storage node material 120 may have a thickness extending in the X-direction within a range of from about 4 nm to about 6 nm.

The tunneling material 122 may be formed (e.g., conformally formed) laterally adjacent to the storage node material 120. The tunneling material 122 may be formed as a so-called “oxide-nitride-oxide” (ONO) structure (e.g., an interlayer poly dielectric structure). The tunneling material 122 may have an at least substantially uniform thickness extending in the X-direction. In some embodiments, the tunneling material 122 may have a thickness extending in the X-direction within a range of from about 4 nm to about 8 nm.

The channel material 124 may be formed (e.g., conformally formed) laterally adjacent to the tunneling material 122. For example, the channel material 124 may be formed by conventional CVD or conventional ALD processes. The material of the channel material 124 may be doped polysilicon, undoped polysilicon, or any other suitable channel material. As a non-limiting example, the channel material 124 may be formed of polysilicon. The channel material 124 may have an at least substantially uniform thickness extending in the X-direction. In some embodiments, the channel material 124 may have a thickness extending in the X-direction within a range of from about 3 nm to about 11 nm.

A fill material 126 may be formed by conventional techniques within the pillar opening 112 to form a pillar 128 (e.g., a memory pillar) including the fill material 126 and the cell films 114. The fill material 126 may be formed of and include any suitable dielectric composition. The fill material 126 may extend between the channel materials 124 on either side of the pillar opening 112 and function as a structural support within the electronic device 100. The fill material 126 may at least substantially fill a remainder of the pillar opening 112 adjacent to the channel material 124. The channel material 124 may at least substantially surround the fill material 126. Therefore, the cell films 114 and the fill material 126 at least substantially completely fill the pillar opening 112.

The conductive materials 106 of the stack structure 104 may be formed by a so-called “replacement gate” process conducted before the process stage shown in FIG. 1A. For example, before formation of the conductive materials 106, the stack structure 104 may include vertically alternating nitride materials (not shown) and the dielectric materials 108. Tiers 110 may each individually include a vertically adjacent nitride material and dielectric material 108 before formation of the conductive materials 106. After formation of the pillar opening 112, the cell films 114, and the fill material 126, the nitride materials may be selectively removed by conventional techniques, such as by a wet etch process, to form first openings (not shown) in the stack structure 104. Conventional etch chemistries and etch conditions may be used to remove the nitride materials depending on the material(s) used for the nitride materials. The etch chemistries and etch conditions may selectively remove the nitride materials without substantially removing the dielectric materials 108 or the cell films 114. After removing the nitride materials, the conductive materials 106 may be formed in the first openings, as shown in FIG. 1A.

The conductive materials 106 may be formed by one or more conventional deposition processes, which are not described in detail herein. The conductive materials 106 may include any suitable electrically conductive composition. In some embodiments, the conductive materials 106 include, consist essentially of, or consist of tungsten. The conductive materials 106 may each be at least substantially planar, and may each independently exhibit any suitable height. In some embodiments, a height of the conductive materials 106 may be within a range of from about 10 nm to about 400 nm. In some embodiments, the conductive materials 106 may have a height within a range of from about 10 nm to about 50 nm. Each of the conductive materials 106 may be at least substantially the same (e.g., exhibit substantially the same material composition, material distribution, size, and shape) as one another, or at least one of the conductive materials 106 may be different (e.g., exhibit one or more of a different material composition, a different material distribution, a different size, and a different shape) than at least one other conductive material 106.

Referring to FIG. 1B, the dielectric materials 108 are selectively removed to form second openings 130 in the stack structure 104. The dielectric materials 108 may be removed by conventional techniques, such as by a wet etch process. Conventional etch chemistries and etch conditions may be used to remove the dielectric materials 108 depending on the material(s) used for the dielectric materials 108 and the conductive materials 106 and the cell films 114. The etch chemistries and etch conditions may selectively remove the dielectric materials 108 without substantially removing the conductive materials 106 or the cell films 114. The first high-k dielectric material 116 may be exposed within the second openings 130 following the removal of the dielectric materials 108.

As shown in FIG. 1C, portions of the first high-k dielectric material 116, the barrier oxide material 118, and the storage node material 120 proximal to the second openings 130 may be selectively removed by conventional techniques, such as a wet etch process or a vapor etch process. The portions of the first high-k dielectric material 116, the barrier oxide material 118, and the storage node material 120 may be removed by a single removal process or by multiple, sequential removal processes. Conventional etch chemistries and etch conditions may be used to remove the portions of the first high-k dielectric material 116, the barrier oxide material 118, and the storage node material 120 proximal to the second openings 130 depending on the materials used for each of the first high-k dielectric material 116, the barrier oxide material 118, and the storage node material 120. The etch chemistries and etch conditions may selectively remove the portions of the first high-k dielectric material 116, the barrier oxide material 118, and the storage node material 120 without substantially removing the conductive material 106, the tunneling material 122, or the channel material 124. Therefore, the tunneling material 122 and the channel material 124 extend substantially continuously in the pillar opening 112 while discontinuous portions (e.g., segments, discrete segments) of the first high-k dielectric material 116, the barrier oxide material 118, and the storage node material 120 are formed. The segments of the first high-k dielectric material 116, the barrier oxide material 118, and the storage node material 120 are adjacent to (e.g., laterally adjacent to) the conductive materials 106.

The segments of the first high-k dielectric material 116, the barrier oxide material 118, and the storage node material 120 may exhibit any suitable length extending vertically (e.g., in the Z-direction). In some embodiments, the segments of the first high-k dielectric material 116, the barrier oxide material 118, and the storage node material 120 exhibit respective lengths that are at least substantially greater than or equal to a height in the Z-direction of the conductive materials 106. For example, the segments of the first high-k dielectric material 116, the barrier oxide material 118, and the storage node material 120 may exhibit a length within a range of from about 15 nm to about 30 nm, such as from about 15 nm to about 20nm, from about 15 nm to about 25 nm, from about 20 nm to about 25 nm, from about 20 nm to about 30 nm, or from about 25 nm to about 30 nm. The segments of the first high-k dielectric material 116, the barrier oxide material 118, and the storage node material 120 may exhibit at least substantially the same length as one another, or at least one of the segments of the first high-k dielectric material 116, the barrier oxide material 118, and the storage node material 120 may exhibit a different length than at least one other segment of the first high-k dielectric material 116, the barrier oxide material 118, and/or the storage node material 120.

Referring to FIG. 1D, dielectric materials 132 may be formed within the second openings 130 (FIG. 1C) vertically adjacent to the conductive materials 106. The dielectric materials 132 include two or more dielectric materials that function as a so-called “seal” for the conductive materials 106. The multiple dielectric materials of the seal are between vertically adjacent conductive materials 106, which function as access lines (e.g., word lines) of the electronic device 100. Therefore, the dielectric materials 132 provide a seal for the word lines. The dielectric materials 132 may be formed to at least partially fill the second openings 130. The dielectric materials 132 may include at least one first oxide material 134, at least one nitride material 136, and, optionally, at least one second high-k dielectric material 138 and/or at least one second oxide material. In some embodiments, the dielectric materials 132 consist of the at least one first oxide material 134, the at least one nitride material 136, and the at least one second high-k dielectric material 138, as depicted in FIG. 1D. In other embodiments, the dielectric materials 132 consist of the at least one first oxide material 134, the at least one nitride material 136, and the at least one second oxide material (not shown), and do not include the at least one second high-k dielectric material 138. In additional embodiments, the dielectric materials 132 consist of the at least one first oxide material 134, the at least one nitride material 136, the at least one second high-k dielectric material 138, and the at least one second oxide material (not shown). In some embodiments, the dielectric materials 132 consist of the at least one first oxide material 134 formed of and including silicon dioxide, the at least one nitride material 136 formed of and including silicon nitride, and the at least one second high-k dielectric material 138 formed of and including aluminum oxide. By including multiple materials and appropriately selecting the materials of the dielectric materials 132, breakdown voltage and program erase window of the electronic device 100 may be increased.

FIG. 1E illustrates a simplified partial top-down cross-sectional view of the electronic device 100 taken along the A-A line of FIG. 1D extending horizontally (e.g., in the X-direction) through the dielectric materials 132. An enlarged view of an individual memory cell 142 is shown in the cross-sectional view of FIG. 2, which is an enlarged view of the circled region indicated by the dashed lines in FIG. 1D. Referring to FIG. 1D in combination with FIGS. 1E and 2, the dielectric materials 132 may include the at least one first oxide material 134 vertically adjacent (e.g., directly vertically adjacent) to the conductive materials 106, the first high-k dielectric material 116, the barrier oxide material 118, and the storage node material 120, and laterally adjacent (e.g., directly laterally adjacent) to the tunneling material 122. The at least one nitride material 136 may be vertically adjacent (e.g., directly vertically adjacent) and laterally adjacent (e.g., directly laterally adjacent) to the at least one first oxide material 134. The first oxide material 134 may at least substantially surround the at least one nitride material 136. In some embodiments, the dielectric materials 132 include the at least one second high-k dielectric material 138 vertically adjacent (e.g., directly vertically adjacent) and laterally adjacent (e.g., directly laterally adjacent) to the at least one nitride material 136, as depicted in FIGS. 1D and 1E. In some embodiments, the at least one second oxide (not shown) is vertically adjacent (e.g., directly vertically adjacent) and laterally adjacent (e.g., directly laterally adjacent) to the at least one second high-k dielectric material 138. In other embodiments, the dielectric materials 132 include the at least one second oxide (not shown) vertically adjacent (e.g., directly vertically adjacent) and laterally adjacent (e.g., directly laterally adjacent) to the at least one nitride material 136.

The dielectric materials 132 are depicted in FIGS. 1D and 2 as having an at least substantially rectangular cross-sectional shape when viewed in the X-Z plane. However, the dielectric materials 132 may exhibit any suitable cross-sectional shape when viewed in the X-Z plane, such as, for example, a rounded profile or a polygonal profile. Components (e.g., the at least one first oxide material 134, the at least one nitride material 136 and, optionally, the at least one second high-k dielectric material 138 and/or at least one second oxide material) of the dielectric materials 132 may each exhibit at least substantially the same profile shape or at least one component of the dielectric materials 132 may exhibit a different profile shape than at least one other component of the dielectric materials 132.

The at least one first oxide material 134 may include any suitable dielectric oxide composition. For example, the at least one first oxide material 134 may include, consist essentially of, or consist of silicon dioxide. The at least one first oxide material 134 may be formed using one or more conventional deposition processes (e.g., a PVD process, a CVD process, an ALD process). The at least one first oxide material 134 may be formed to exhibit a thickness within a range of from about 2 nm to about 5 nm, such as from about 2 nm to about 3nm, from about 2 nm to about 4 nm, from about 3 nm to about 4 nm, from about 3 nm to about 5nm, or from about 4 nm to about 5 nm. The at least one first oxide material 134 may at least substantially continuously extend over surfaces of the conductive materials 106, the first high-k dielectric material 116, the barrier oxide material 118, the storage node material 120, and the tunneling material 122 defining the second openings 130.

The at least one nitride material 136 may include one or more of silicon nitride and silicon oxynitride. The at least one nitride material 136 may include a stoichiometric nitride material or a non-stoichiometric nitride material. In some embodiments, the at least one nitride material 136 includes, consists essentially of, or consists of silicon nitride. The at least one nitride material 136 may be formed using one or more conventional deposition processes (e.g., a PVD process, a CVD process, an ALD process). The at least one nitride material 136 may be formed to exhibit a thickness within a range of from about 0.5 nm to about 2.0 nm, such as from about 0.5 nm to about 1.0 nm, from about 0.5 nm to about 1.5 nm, from about 1.0 nm to about 1.5 nm, from about 1.0 nm to about 2.0 nm, or from about 1.5 nm to about 2.0 nm. The at least one nitride material 136 may at least substantially continuously extend over a surface of the at least one first oxide material 134.

The at least one second high-k dielectric material 138 may include one or more high-k dielectric materials, such as, for example, one or more of aluminum oxide, gadolinium oxide, hafnium oxide, niobium oxide, tantalum oxide, titanium oxide, zirconium oxide, hafnium silicate, a combination thereof, or a combination of one or more of the listed high-k dielectric materials with silicon oxide. In some embodiments, the at least one second high-k dielectric material 138 includes, consists essentially of, or consists of one or more of aluminum oxide, hafnium oxide, and zirconium oxide. In some embodiments, the at least one second high-k dielectric material 138 includes, consists essentially of, or consists of aluminum oxide. The at least one second high-k dielectric material 138 may be formed using one or more conventional deposition processes (e.g., a PVD process, a CVD process, an ALD process). The at least one second high-k dielectric material 138 may be formed to exhibit a thickness within a range of from about 0.5 nm to about 2.0 nm, such as from about 0.5 nm to about 1.0 nm, from about 0.5nm to about 1.5 nm, from about 1.0 nm to about 1.5 nm, from about 1.0 nm to about 2.0 nm, or from about 1.5 nm to about 2.0 nm. The at least one second high-k dielectric material 138 may at least substantially continuously extend over a surface of the at least one nitride material 136. In some embodiments, the at least one second high-k dielectric material 138 is not present (e.g., is omitted) from the electronic device 100.

The at least one second oxide material, if present, may include any suitable dielectric oxide composition. For example, the at least one second oxide material may include, consist essentially of, or consist of silicon dioxide. In some embodiments, the at least one second oxide material is formed of and includes the same material(s) of the at least one first oxide material 134. The at least one second oxide material may be formed using one or more conventional deposition processes (e.g., a PVD process, a CVD process, an ALD process). The at least one second oxide material may be formed to exhibit a thickness within a range of from about 3 nm to about 12 nm. The at least one second oxide material may extend at least substantially continuously over a surface of the at least one nitride material 136 or a surface of the at least one second high-k dielectric material 138. In some embodiments, the at least one second oxide material is not present (e.g., is omitted) from the electronic device 100.

Depending on the deposition process used, the dielectric materials 132 may define air gaps 140 between vertically adjacent conductive materials 106. The air gaps 140 may have any suitable configuration depending on the amount of the dielectric materials 132 (e.g., the at least one first oxide material 134, the at least one nitride material 136 and, optionally, the at least one second high-k dielectric material 138 and/or at least one second oxide material) formed in the second openings 130. The air gaps 140 are depicted in FIGS. 1D and 2 as having a rectangular cross-sectional shape when viewed in the X-Z plane. However, the air gaps 140 may exhibit any suitable cross-sectional shape when viewed in the X-Z plane, such as, for example, a rounded profile or a polygonal profile. The dielectric materials 132 may provide leakage prevention to the electronic device 100 while the air gaps 140 may provide capacitance reduction. The air gaps 140 may account for at least about 50% by volume of a total volume of the second openings 130 depending on the thickness of the dielectric materials 132 formed in the second openings 130. In other words, the dielectric materials 132 may occupy less than about 50% by volume of the second openings 130. However, the dielectric materials 132 may occupy at least substantially all of the second openings 130 depending on desired electrical performance.

Referring to FIG. 1D, the electronic device 100 includes the stack structure 104 with tiers 110 of vertically alternating dielectric materials 132 and conductive materials 106. The pillar 128 including the fill material 126 and the cell films 114 is located within the pillar opening 112 and extends vertically through the dielectric materials 132 and conductive materials 106 of the stack structure 104. The dielectric materials 132 include the first oxide material 134, the nitride material 136, and the optional second high-k dielectric material 138. The dielectric materials 132 include the air gaps 140 within (e.g., defined by) the dielectric materials 132. Individual conductive materials 106 of the stack structure 104 and portions of the cell films 114 laterally adjacent to the individual conductive materials 106 may form an individual memory cell 142. A vertical stack of multiple memory cells 142 within the pillar opening 112 may form a vertical string (e.g., vertical series) of the memory cells 142. The illustrated memory cells 142 in the vertical string may be representative of a large number of substantially identical memory cells formed during fabrication of the electronic device 100. By way of a non-limiting example, the electronic device 100 includes three-dimensional (3D) NAND Flash memory cells. One or more of the lowermost conductive materials 106 may be configured as select gate sources (“SGSs”). One or more of the uppermost conductive materials 106 may be configured as select gate drains (“SGDs”). The conductive materials 106 between the SGS(s) and the SGD(s) may be configured as access lines (e.g., word lines).

Accordingly, a method of forming an electronic device includes forming a stack structure including pillar openings extending through vertically alternating conductive and sacrificial dielectric materials, and cell films within the pillar openings, the cell films adjacent to the conductive and sacrificial dielectric materials. The cell films include a first high-k dielectric material, a barrier oxide material, a storage node material, a tunneling material, and a channel material. The method includes removing the sacrificial dielectric materials to form openings in the stack structure, selectively removing exposed portions of the first high-k dielectric material, the barrier oxide material, and the storage node material proximal to the openings, and forming dielectric materials in the openings to at least partially fill the openings. Forming the dielectric materials includes forming a first oxide material in the openings and forming a nitride material over the first oxide material in the openings.

Accordingly, an electronic device includes a stack structure including vertically alternating dielectric materials and conductive materials. The dielectric materials define air gaps between vertically adjacent conductive materials and include a first oxide material vertically adjacent to the conductive materials and laterally adjacent to the tunneling material, and a nitride material laterally and vertically adjacent to the first oxide material. The stack structure includes pillars extending vertically through the stack structure, the pillars including cell films adjacent to the dielectric and conductive materials. The cell films include a high-k dielectric material, a barrier oxide material, a storage node material, a tunneling material, and a channel material, wherein segments of each of the high-k dielectric material, the barrier oxide material, and the storage node material are adjacent to the conductive materials.

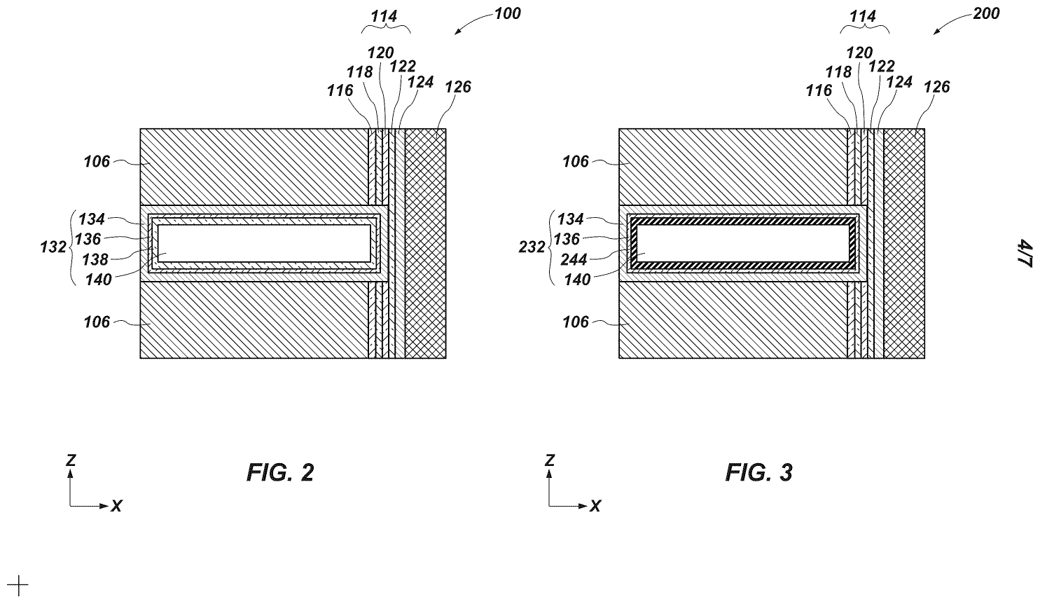

An enlarged view of an individual memory cell of an electronic device 200 according to other embodiments of the disclosure is shown in FIG. 3. The electronic device 200 may be at least substantially similar to the electronic device 100 previously described with reference to FIGS. 1D through 2, and may be formed by substantially the same process previously described with reference to FIGS. 1A through 1D. Unless otherwise specified, the material types, material thicknesses, etc., of the electronic device 200 are as described above for FIGS. 1A through 2. The electronic device 200 differs from the electronic device 100 in the configuration of the dielectric materials 232. The dielectric materials 232 include the at least one first oxide material 134, the at least one nitride material 136, and at least one second oxide material 244. The at least one first oxide material 134 is vertically adjacent (e.g., directly vertically adjacent) to the conductive materials 106, the first high-k dielectric material 116, the barrier oxide material 118, and the storage node material 120, and laterally adjacent (e.g., directly laterally adjacent) to the tunneling material 122. The at least one nitride material 136 is adjacent (e.g., directly adjacent) to the at least one first oxide material 134. The at least one second oxide material 244 is adjacent (e.g., directly adjacent) to the at least one nitride material 136. The nitride material 136 is disposed between the at least one first oxide material 134 and the at least one second oxide material 244. The at least one second oxide material 244 is substantially similar to the at least one second oxide material previously discussed with reference to FIGS. 1D and 2. In some embodiments, the at least one second oxide material 244 is formed of and includes the same material(s) of the at least one first oxide material 134. The dielectric materials 232 may be at least substantially free of aluminum oxide, gadolinium oxide, hafnium oxide, niobium oxide, tantalum oxide, titanium oxide, zirconium oxide, hafnium silicate, or a combination thereof. The dielectric materials 232 may include the air gaps 140 within (e.g., defined by) the dielectric materials 232. The air gaps 140 may be defined by a surface of the at least one second oxide material 244.

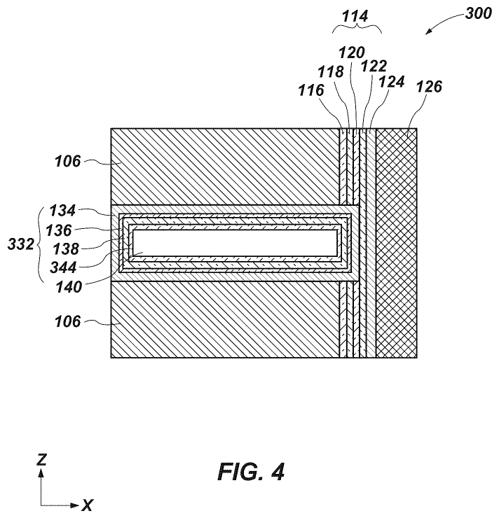

An enlarged view of an individual memory cell of an electronic device 300 according to yet other embodiments of the disclosure is shown in FIG. 4. The electronic device 300 may be at least substantially similar to the electronic device 100 previously described with referenced to FIGS. 1A through 2, and may be formed by at least substantially the same process previously described with reference to FIGS. 1A through 1D. Unless otherwise specified, the material types, material thicknesses, etc., of the electronic device 300 are as described above for FIGS. 1A through 2. The electronic device 300 differs from the electronic device 100 in the configuration of dielectric materials 332. The dielectric materials 332 include the at least one first oxide material 134, the at least one nitride material 136, the at least one second high-k dielectric material 138, and at least one second oxide material 344. The at least one first oxide material 134 is vertically adjacent (e.g., directly vertically adjacent) to the conductive materials 106, the first high-k dielectric material 116, the barrier oxide material 118, and the storage node material 120, and laterally adjacent (e.g., directly laterally adjacent) to the tunneling material 122. The at least one nitride material 136 is adjacent (e.g., directly adjacent) to the at least one first oxide material 134. The at least one second high-k dielectric material 138 is adjacent (e.g., directly adjacent) to the at least one nitride material 136. The at least one second oxide material 344 is adjacent (e.g., directly adjacent) to the at least one second high-k dielectric material 138. The at least one nitride material 136 is disposed between the at least one first oxide material 134 and the at least one second high-k dielectric material 138. The at least one second high-k dielectric material 138 is disposed between the at least one nitride material 136 and the at least one second oxide material 344. The at least one second oxide material 344 is substantially similar to the at least one second oxide material previously discussed with reference to FIGS. 1D and 2. In some embodiments, the at least one second oxide material 344 is formed of and includes the same material(s) of the at least one first oxide material 134. The dielectric materials 332 may include the air gaps 140 within (e.g., defined by) the dielectric materials 332. The air gaps 140 may be defined by a surface of the at least one second oxide material 344.

Conventional electronic devices including conventional dielectric materials between memory cells include a single dielectric composition, such as silicon dioxide, exhibiting poor (e.g., low) dielectric breakdown voltages. The electronic devices 100, 200, 300 including the dielectric materials 132, 232, 332 including the at least one nitride material 136 and, optionally, the at least one second high-k dielectric material 138 exhibit an improved breakdown voltage relative to conventional electronic devices including conventional dielectric materials lacking the at least one nitride material 136 and the at least one second high-k dielectric material 138. For example, the electronic devices 100, 200, 300 including the dielectric materials 132, 232, 332 may exhibit a breakdown voltage of up to 2.3 times greater than a breakdown voltage of electronic devices including conventional dielectric materials. In some embodiments, the electronic devices 100, 200, 300 including the dielectric materials 132, 232, 332 exhibit a breakdown voltage of at least about 20 V. Without being bound by any theory, the at least one nitride material 136 of the dielectric materials 132, 232, 332 may act as an electron sink, collecting back injected electrons and preventing electron back injection into the memory cells 142. By preventing electron back injection, the program/erase window of the electronic devices 100, 200, 300 is increased relative to conventional electronic devices including a single dielectric material proximal to the conductive materials. A greater distance between the nitride material 136 and the barrier oxide material 118 may enable more efficient hole trapping, which improves erase. In addition to increasing breakdown voltage and program erase window, the dielectric materials 132 improve leakage between adjacent conductive materials 106 (e.g., word lines).

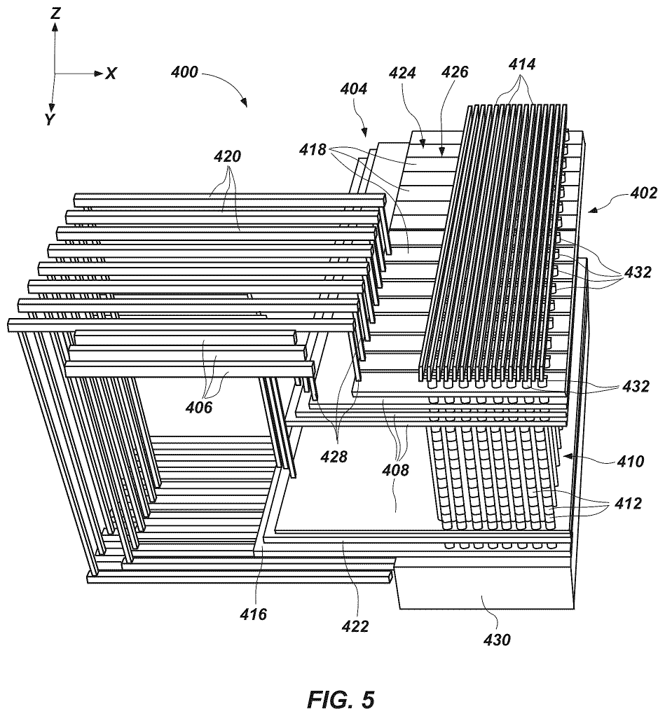

FIG. 5 illustrates a partial cutaway perspective view of a portion of an electronic device 400 (e.g., a microelectronic device, a memory device, such as a 3D NAND Flash memory device) including an electronic structure 402 (e.g., a microelectronic device structure). The electronic structure 402 may be substantially similar to the electronic devices 100, 200, 300 previously described with reference to FIGS. 1A through 4. For convenience in describing FIG. 5, a first direction may be defined as the X-direction. A second direction, which is transverse (e.g., perpendicular) to the first direction may be defined as the Y-direction. A third direction, which is transverse (e.g., perpendicular) to the first and second directions may be defined as the Z-direction.

As shown in FIG. 5, the electronic structure 402 may include a staircase structure 404 defining contact regions for connecting access lines 406 to conductive structures 408 (e.g., corresponding to at least a portion of the conductive materials 106 (FIG. 1D)). The electronic structure 402 may include vertical strings 410 of memory cells 412 (e.g., the memory cells 142 (FIG. 1D)) that are coupled to each other in series. The vertical strings 410 may extend vertically (e.g., in the Z-direction) and orthogonally to the conductive structures 408, and other conductive structures, such as data lines 414, a source tier 416, first select gates 418 (e.g., upper select gates, select gates drains (SGDs)), select lines 420, and a second select gate 422 (e.g., a lower select gate, a source select gate (SGS)). The first select gates 418 may be horizontally divided (e.g., in the Y-direction) into multiple blocks 424 horizontally separated from one another by slots 426.

Vertical conductive contacts 428 may electrically couple components to each other as shown. For example, the select lines 420 may be electrically coupled to the first select gates 418 and the access lines 406 may be electrically coupled to the conductive structures 408. The electronic device 400 may also include a control unit 430 positioned under the memory array, which may include at least one of string driver circuitry, pass gates, circuitry for selecting gates, circuitry for selecting conductive lines (e.g., the data lines 414, the access lines 406), circuitry for amplifying signals, and circuitry for sending signals. The control unit 430 may be electrically coupled to the data lines 414, the source tier 416, the access lines 406, the first select gates 418, and the second select gate 422, for example. In some embodiments, the control unit 430 includes CMOS (complementary metal-oxide-semiconductor) circuitry. In such embodiments, the control unit 430 may be characterized as having a “CMOS under Array” (“CuA”) configuration.

The first select gates 418 may extend horizontally in a first direction (e.g., the X-direction) and may be coupled to respective first groups of vertical strings 410 of memory cells 412 at a first end (e.g., an upper end) of the vertical strings 410. The second select gate 422 may be formed in a substantially planar configuration and may be coupled to the vertical strings 410 at a second, opposite end (e.g., a lower end) of the vertical strings 410 of memory cells 412.

The data lines 414 (e.g., digit lines, bit lines) may extend horizontally in a second direction (e.g., in the Y-direction) that is at an angle (e.g., perpendicular) to the first direction (e.g., the X-direction) in which the first select gates 418 extend. Individual data lines 414 may be coupled to individual groups of the vertical strings 410 extending in the second direction (e.g., the Y-direction) at the first end (e.g., the upper end) of the vertical strings 410 of the individual groups. Additional individual groups of the vertical strings 410 extending in the first direction (e.g., the X-direction) and coupled to individual first select gates 418 may share a particular vertical string 410 thereof with individual groups of vertical strings 410 coupled to an individual data line 414. Thus, an individual vertical string 410 of memory cells 412 may be selected at an intersection of an individual first select gate 418 and an individual data line 414. Accordingly, the first select gates 418 may be used for selecting memory cells 412 of the vertical strings 410 of memory cells 412.

The conductive structures 408 (e.g., word lines) may extend in respective horizontal planes. The conductive structures 408 may be stacked vertically, such that each conductive structure is coupled to at least some of the vertical strings 410 of memory cells 412, and the vertical strings 410 of the memory cells 412 extend vertically through the stack structure including the conductive structures 408. The conductive structures 408 may be coupled to or may form control gates of the memory cells 412.

The first select gates 418 and the second select gate 422 may operate to select a vertical string 410 of memory cells 412 interposed between data lines 414 and the source tier 416. Thus, an individual memory cell 412 may be selected and electrically coupled to a data line 414 by operation of (e.g., by selecting) the appropriate first select gate 418, second select gate 422, and conductive structure 408 that are coupled to the particular memory cell 412.

The staircase structure 404 may be configured to provide electrical connection between the access lines 406 and the conductive structures 408 through the vertical conductive contacts 428. In other words, an individual conductive structure 408 may be selected via an access line 406 in electrical communication with a respective vertical conductive contact 428 in electrical communication with the conductive structure 408. The data lines 414 may be electrically coupled to the vertical strings 410 of memory cells 412 through conductive contact structures 432.

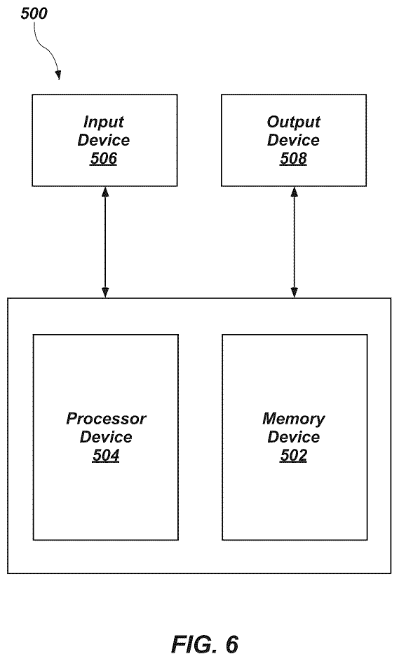

Electronic devices (e.g., the electronic devices 100, 200, 300) including the dielectric materials 132, 232, 332, according to embodiments of the disclosure may be used in embodiments of electronic systems of the disclosure. For example, FIG. 6 is a block diagram of an electronic system 500, in accordance with embodiments of the disclosure. The electronic system 500 may include, for example, a computer or computer hardware component, a server or other networking hardware component, a cellular telephone, a digital camera, a personal digital assistant (PDA), portable media (e.g., music) player, a Wi-Fi or cellular-enabled tabled such as, for example, an iPAD® or SURFACE® tablet, an electronic book, a navigation device, etc. The electronic system 500 includes at least one memory device 502. The memory device 502 may include, for example, one or more embodiments of an electronic device previously described herein (e.g., the electronic devices 100, 200, 300, 400 previously described with reference to FIGS. 1A through 5) including the dielectric materials 132, 232, 332.

The electronic system 500 may further include at least one electrical signal processor device 504 (e.g., a microprocessor). The electrical signal processor device 504 may, optionally, include an embodiment of an electronic device previously described herein (e.g., the electronic devices 100, 200, 300, 400 previously described with reference to FIGS. 1A through 5). The electronic system 500 may further include one or more input devices 506 for inputting information into the electronic system 500 by a user, such as, for example, a mouse or other pointing device, a keyboard, a touchpad, a button, or a control panel. The electronic system 500 may further include one or more output devices 508 for outputting information (e.g., visual or audio output) to a user such as, for example, a monitor, a display, a printer, an audio output jack, a speaker, etc. In some embodiments, the input device 506 and the output device 508 may include a single device that can be used to both input information to the electronic system 500 and to output information to a user. For example, the input device 506 and the output device 508 may include a single touchscreen device that can input information from a user to the electronic system 500 and output visual information to a user. The input device 506 and the output device 508 may communicate electrically with one or more of the memory device 502 and the electrical signal processor devices 504.

Accordingly, a system includes a processor operably coupled to an input device and an output device and a memory device operably coupled to the processor, the memory device including at least one electronic device. The at least one electronic device includes a stack structure including tiers of vertically alternating dielectric and conductive materials, the dielectric materials including a first oxide material and a nitride material laterally and vertically adjacent to the first oxide material, and strings of memory cells vertically extending through the stack structure. One or more of the memory cells include a high-k dielectric material laterally adjacent to the conductive materials, a barrier oxide material laterally adjacent to the high-k dielectric material, a storage node material laterally adjacent to the barrier oxide material, a tunneling material laterally adjacent to the storage node material and the first oxide material of the dielectric materials, and a channel material laterally adjacent to the tunneling material.

The electronic devices and systems of the disclosure advantageously facilitate one or more of improved simplicity, greater packaging density, and increase miniaturization of components as compared to conventional structures, conventional devices, and conventional systems. The methods of the disclosure facilitate the formation of devices (e.g., apparatuses, microelectronic devices, memory devices) and systems (e.g., electronic systems) having one or more of improved performance, reliability, and durability, lower costs, increased yield, increased miniaturization of components, improved pattern quality, and greater packaging density as compared to conventional devices (e.g., conventional apparatuses, conventional microelectronic devices, conventional memory devices) and conventional systems (e.g., conventional electronic systems).

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modification to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An electronic device, comprising:
a stack structure comprising:
vertically alternating dielectric materials and conductive materials, the dielectric materials defining air gaps between vertically adjacent conductive materials and comprising a first oxide material vertically adjacent to the conductive materials and laterally adjacent to a tunneling material, and a nitride material laterally and vertically adjacent to the first oxide material; and <pillars extending vertically through the stack structure, the pillars comprising cell films adjacent to the dielectric and conductive materials, the cell films comprising a high-k dielectric material, a barrier oxide material, a storage node material, the tunneling material, and a channel material, wherein segments of each of the high-k dielectric material, the barrier oxide material, and the storage node material are adjacent to the conductive materials.

2. The electronic device of claim 1, wherein the dielectric materials comprise a second high-k dielectric material laterally and vertically adjacent to the nitride material.

3. The electronic device of claim 2, wherein the dielectric materials comprise a second oxide material laterally and vertically adjacent to the second high-k dielectric material.

4. The electronic device of claim 2, wherein the second high-k dielectric material comprises one or more of aluminum oxide, gadolinium oxide, hafnium oxide, niobium oxide, tantalum oxide, titanium oxide, zirconium oxide, hafnium silicate, and combinations of one or more thereof with silicon oxide.

5. The electronic device of claim 1, wherein the dielectric materials comprise a second oxide material laterally and vertically adjacent to the nitride material.

6. The electronic device of claim 5, wherein the second oxide material comprises the same material as the first oxide material.

7. The electronic device of claim 1, wherein the nitride material comprises one or more of silicon nitride and silicon oxynitride.

8. The electronic device of claim 1, wherein the first oxide material exhibits a thickness within a range of from about 2 nm to about 5 nm.

9. A method of forming an electronic device, the method comprising:
forming a stack structure comprising pillar openings extending through vertically alternating
conductive and sacrificial dielectric materials, and cell films within the pillar openings,
the cell films adjacent to the conductive and sacrificial dielectric materials and comprising a first high-k dielectric material, a barrier oxide material, a storage node material, a tunneling material, and a channel material;
removing the sacrificial dielectric materials to form openings in the stack structure;
selectively removing exposed portions of the first high-k dielectric material, the barrier oxide material, and the storage node material proximal to the openings; and
forming dielectric materials in the openings to at least partially fill the openings, wherein
forming the dielectric materials comprises:
forming a first oxide material in the openings; and
forming a nitride material over the first oxide material in the openings.

10. The method of claim 9, wherein:
selectively removing exposed portions of the first high-k dielectric material, the barrier oxide material, and the storage node material comprises forming segments of the first high-k dielectric material, the barrier oxide material, and the storage node material laterally adjacent to the conductive materials; and
forming the dielectric materials comprises conformally forming the first oxide material vertically adjacent to the conductive materials and the segments of the first high-k dielectric material, the barrier oxide material, and the storage node material, and laterally adjacent to exposed portions of the tunneling material.

11. The method of claim 10, wherein forming the nitride material over the first oxide material in the openings comprises conformally forming the nitride material adjacent to the first oxide material.

12. The method of claim 9, wherein forming the dielectric materials further comprises forming one or more of a second high-k dielectric material and a second oxide material over the nitride material in the openings.

13. The method of claim 12, wherein forming the dielectric materials comprises:
forming the second high-k dielectric material over the nitride material in the openings; and
forming the second oxide material over the second high-k dielectric material in the openings. 14 The method of claim 9, wherein forming the dielectric materials further comprises forming an air gap in the dielectric materials.

15. The method of claim 9, wherein forming the dielectric materials comprises forming the dielectric materials to at least substantially continuously extend over surfaces of the conductive materials, the first high-k dielectric material, the barrier oxide material, the storage node material, and the tunneling material defining the openings in the stack structure.

16. A system, comprising:
a processor operably coupled to an input device and an output device; and
a memory device operably coupled to the processor and comprising at least one electronic device, the at least one electronic device comprising:
a stack structure comprising tiers of vertically alternating dielectric and conductive materials, the dielectric materials comprising a first oxide material and a nitride material laterally and vertically adjacent to the first oxide material; and
strings of memory cells vertically extending through the stack structure, one or more of the memory cells comprising:
a high-k dielectric material laterally adjacent to the conductive materials, a barrier oxide material laterally adjacent to the high-k dielectric material, a storage node material laterally adjacent to the barrier oxide material, a tunneling material laterally adjacent to the storage node material and the first oxide material of the dielectric materials, and a channel material laterally adjacent to the tunneling material.

17. The system of claim 16, wherein the dielectric materials further comprise a second high-k dielectric material laterally and vertically adjacent to the nitride material.

18. The system of claim 16, wherein the dielectric materials further comprise a second oxide material laterally and vertically adjacent to the nitride material.

19. The system of claim 16, wherein the dielectric materials exhibit a breakdown voltage of at least about 20 V.

20. The system of claim 16, wherein the first oxide material has a thickness within a range of from about 2 nm to about 5 nm and the nitride material has a thickness within a range of from about 0.5 nm to about 2 nm.
